(19) United States
(12) Patent Application Publication
(10) Pub. No.: US 2022/0173358 A1
(43) Pub. Date: Jun. 2, 2022

(54) DISPLAY DEVICE, ELECTRONIC DEVICE, AND METHOD FOR MANUFACTURING DISPLAY DEVICE

(71) Applicant: SONY SEMICONDUCTOR SOLUTIONS CORPORATION, KANAGAWA (JP)

(72) Inventor: KENTA HIRAGA, TOKYO (US)

(21) Appl. No.: 17/593,314

(22) PCT Filed: Feb. 12, 2020
(86) PCT No.: PCT/JP2020/005353

§ 371 Date: Sep. 15, 2021

(30) Foreign Application Priority Data
Mar. 26, 2019 (JP) 2019-058564

(51) Int. Cl. H01L 51/52; H01L 27/32; H01L 51/56

(52) U.S. Cl. CPC H01L 51/5271; H01L 27/3246; H01L 2227/323; H01L 27/3283; H01L 27/322; H01L 51/56

(57) ABSTRACT

A display device provided with OLEDs improves the quality of an image. The display device includes a pixel array. A plurality of sub-pixels is arranged on the display surface of the pixel array. Furthermore, in the pixel array included in the display device, each of the plurality of sub-pixels is provided with a light-emitting portion and a reflector. At each of the plurality of sub-pixels arranged in the pixel array included in the display device, the reflector reflects light emitted from the light-emitting portion in a direction toward the central axis of the display surface.

### TECHNICAL FIELD

The present technology relates to a display device. More specifically, the present technology relates to a display device using light-emitting elements, an electronic device, and a method for manufacturing the display device.

### BACKGROUND ART

Organic light-emitting diodes (OLEDs) have conventionally been used in various display devices, with their characteristics such as allowing low power consumption and film thinning and high response speed taken into consideration. For example, a display device in which color filters of red (R), green (G), and blue (B) or the like and OLEDs are disposed at each pixel has been proposed (see, for example, Patent Document 1).

### CITATION LIST

### Patent Document

Patent Document 1: Japanese Patent Application Laid-Open No. 2017-146372

### SUMMARY OF THE INVENTION

### Problems To Be Solved By The Invention

In the above conventional technique, the optical distances of the chief rays from the OLEDs are adjusted differently for each color of R, G, and B to set the wavelength of each color to an appropriate value. However, in the above-described display device, the directions of the chief rays are set to a direction perpendicular to the display surface at all pixels regardless of the distances from the center of the display device. This can make it harder for the chief rays from the edges of the display device to reach the eyes of the viewer. Consequently, there is a problem that unevenness in brightness occurs in an image viewed by the viewer, reducing the image quality.

The present technology has been invented in view of such circumstances, and an object thereof is to improve the quality of images in a display device provided with OLEDs.

### Solutions To Problems

The present technology has been made to solve the above-described problem. A first aspect thereof is a display device including a pixel array in which a plurality of sub-pixels is arranged on a predetermined display surface, each sub-pixel being provided with a light-emitting portion and a reflector that reflects light emitted from the light-emitting portion in a direction toward the central axis of the display surface. This has the effect of delivering light from each of the plurality of sub-pixels to the viewer on the central axis.

Furthermore, in the first aspect, a difference between an angle of the light reflected by the reflector with respect to the display surface and 90 degrees may decrease with increasing distance from the central axis. This has the effect of reflecting light toward the viewer by the reflector.

Furthermore, in the first aspect, each of the plurality of sub-pixels may be further provided with an anode and a cathode that apply a voltage to the light-emitting portion, the reflector may be formed around the anode, the reflector may have a cone-shaped reflecting surface, and a distance between the center of gravity of a top contour line that is a collection of points on the reflecting surface farthest from the anode and the center of gravity of a bottom contour line that is a collection of points of contact between the anode and the reflecting surface may increase with increasing distance from the central axis to the light-emitting portion. This has the effect of reflecting light toward the viewer by the cone-shaped reflecting surface of the reflector.

Furthermore, in the first aspect, each of the plurality of sub-pixels may be further provided with a color filter that transmits visible light of a predetermined color. This has the effect of displaying a color image.

Furthermore, in the first aspect, a distance between the center of gravity of the color filter and the center of gravity of the sub-pixel may increase with increasing distance from the central axis to the sub-pixel. This has the effect of widening the viewing angle of each color.

Furthermore, a second aspect of the present technology is an electronic device including a pixel array in which a plurality of sub-pixels is arranged on a predetermined display surface, each sub-pixel being provided with a light-emitting portion and a reflector that reflects light emitted from the light-emitting portion in a direction toward the central axis of the display surface, and a driver that drives each of the plurality of sub-pixels. This has the effect of delivering light from each of the plurality of sub-pixels driven by the driver to the viewer on the central axis.

Furthermore, a third aspect of the present technology is a method for manufacturing a display device, including an application step of applying a predetermined resist to a predetermined low-refractive-index material having a lower refractive index than a predetermined organic light-emitting layer, an exposure step of exposing the resist to light by gray-tone exposure, a development step of removing an exposed portion of the resist with a predetermined developer, and an etching step of transferring a pattern of the resist from which the exposed portion has been removed to the low-refractive-index material by etching the low-refractive-index material. This has the effect of manufacturing the display device in which light from each of the plurality of sub-pixels is delivered to the viewer.

Furthermore, in the third aspect, the resist from which the exposed portion has been removed may have a cone-shaped wall surface, and a distance between the center of gravity of a top contour line that is a collection of points on the wall surface farthest from the low-refractive-index material and the center of gravity of a bottom contour line that is a collection of points of contact between the low-refractive-index material and the wall surface may increase with increasing distance from the central axis of a predetermined display surface. This has the effect of forming the reflector that reflects light toward the viewer.

### BRIEF DESCRIPTION OF DRAWINGS

FIG. 1 is an example of an external view of an electronic device according to a first embodiment of the present technology.

FIG. 2 is a block diagram illustrating a configuration example of the electronic device according to the first embodiment of the present technology.

FIG. 3 is an example of a cross-sectional view and a top view of a central sub-pixel according to the first embodiment of the present technology.

FIG. 4 is an example of a cross-sectional view and a top view of a leftmost sub-pixel according to the first embodiment of the present technology.

FIG. 5 is an example of a cross-sectional view and a top view of a rightmost sub-pixel according to the first embodiment of the present technology.

FIG. 6 is an example of a top view of a pixel array according to the first embodiment of the present technology.

FIG. 7 is a diagram for explaining the reflection directions of reflectors according to the first embodiment of the present technology.

FIG. 8 is a diagram for explaining the reflection directions of reflectors according to a comparative example.

FIG. 9 is a diagram illustrating an example of images viewed by the viewer according to the first embodiment of the present technology and the comparative example.

FIG. 10 is a diagram for explaining steps up to gray-tone exposure according to the first embodiment of the present technology.

FIG. 11 is a diagram for explaining steps up to dry etching according to the first embodiment of the present technology.

FIG. 12 is a diagram for explaining steps up to pretreatment and vapor deposition according to the first embodiment of the present technology.

FIG. 13 is a diagram for explaining steps up to sealing according to the first embodiment of the present technology.

FIG. 14 is a flowchart illustrating an example of a method for manufacturing a display device according to the first embodiment of the present technology.

FIG. 15 is an example of a cross-sectional view and a top view of a central sub-pixel according to a second embodiment of the present technology.

FIG. 16 is an example of a cross-sectional view and a top view of a leftmost sub-pixel according to the second embodiment of the present technology.

FIG. 17 is an example of top views of leftmost and central sub-pixels according to the second embodiment of the present technology.

FIG. 18 is a block diagram illustrating a schematic configuration example of a vehicle control system.

FIG. 19 is an explanatory diagram illustrating an example of installation positions of imaging units.

### MODE FOR CARRYING OUT THE INVENTION

Hereinafter, a mode for carrying out the present technology (hereinafter referred to as embodiments) will be described. The description will be made in the following order.

1. First Embodiment (example of reflection toward central axis of display surface)

2. Second Embodiment (example of provision of color filters and reflection toward central axis of display surface)

3. Example of Application to Mobile Object

### 1. First Embodiment

### Configuration Example of Electronic Device

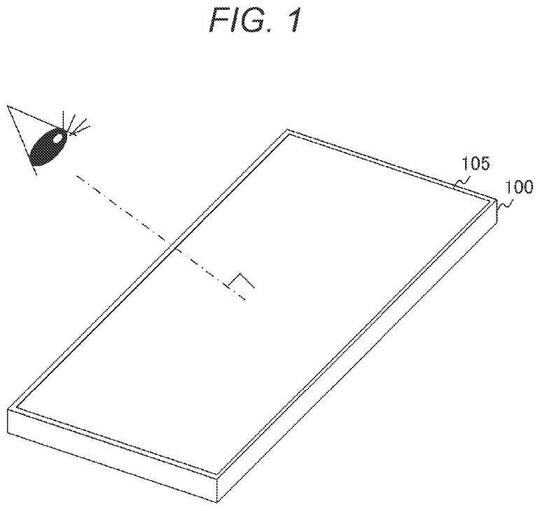

FIG. 1 is an example of an external view of an electronic device 100 according to a first embodiment of the present technology. The electronic device 100 is a device that can display various pieces of information such as images, and has a display surface 105 for displaying those pieces of information. As the electronic device 100, a mobile device such as a smartphone, a virtual reality (VR) terminal, or the like is assumed.

An axis that passes through the center of the display surface 105 and is perpendicular to the display surface 105 is hereinafter referred to as a “central axis”. A dot-dash line in the figure indicates the central axis. It is assumed that the line-of-sight direction when the viewer views an image displayed on the display surface 105 is mainly a direction along the central axis of the display surface 105.

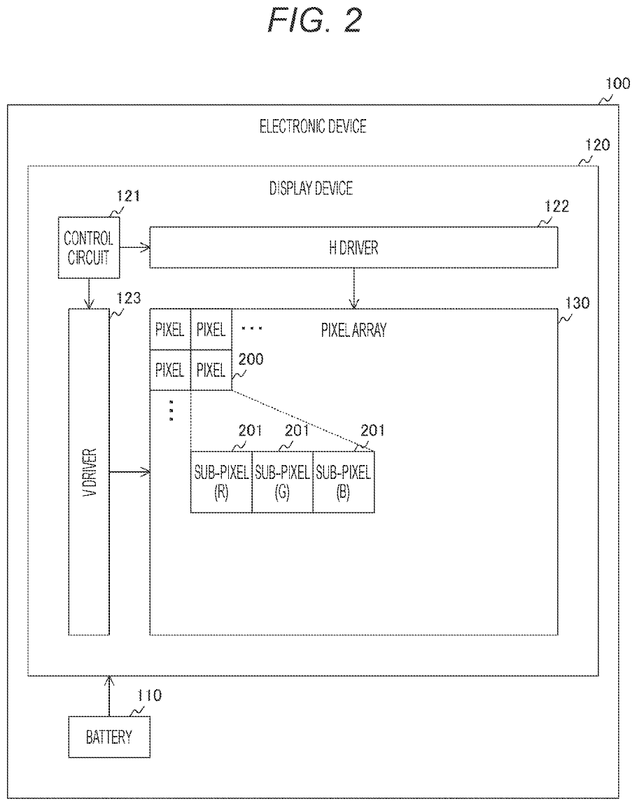

FIG. 2 is a block diagram illustrating a configuration example of the electronic device 100 according to the first embodiment of the present technology. The electronic device 100 includes a display device 120 and a battery 110. Note that in a case where the electronic device 100 is a VR terminal, an optical system including a wide-angle lens is further disposed.

The battery 110 supplies power to the display device 120 by discharging. As the battery 110, for example, a secondary battery capable of charging in addition to discharging is used. As the secondary battery, for example, a lithium-ion battery is used.

The display device 120 includes a control circuit 121, an H driver 122, a V driver 123, and a pixel array 130. The pixel array 130 includes the display surface 105. A plurality of pixels 200 is arranged on the display surface 105 in a two-dimensional grid pattern. Each of the pixels 200 includes a plurality of sub-pixels 201 that emits light of different colors. For example, three sub-pixels 201 that emit light of R, G, and B are disposed at each pixel 200. Note that in the figure, the shape of the sub-pixels 201 is a square, but is not limited to this shape, and may be a rectangle or the like.

Hereinafter, a set of sub-pixels 201 aligned in a predetermined horizontal direction is referred to as a “row”, and a set of sub-pixels 201 aligned in a direction perpendicular to the row is referred to as a “column”.

The control circuit 121 controls the drive timing of each of the H driver 122 and the V driver 123 on the basis of image data. The H driver 122 drives the sub-pixels 201 column by column. The V driver 123 drives the sub-pixels 201 row by row. Note that the H driver 122 and the V driver 123 are an example of a driver described in the claims.

### Pixel Configuration Example

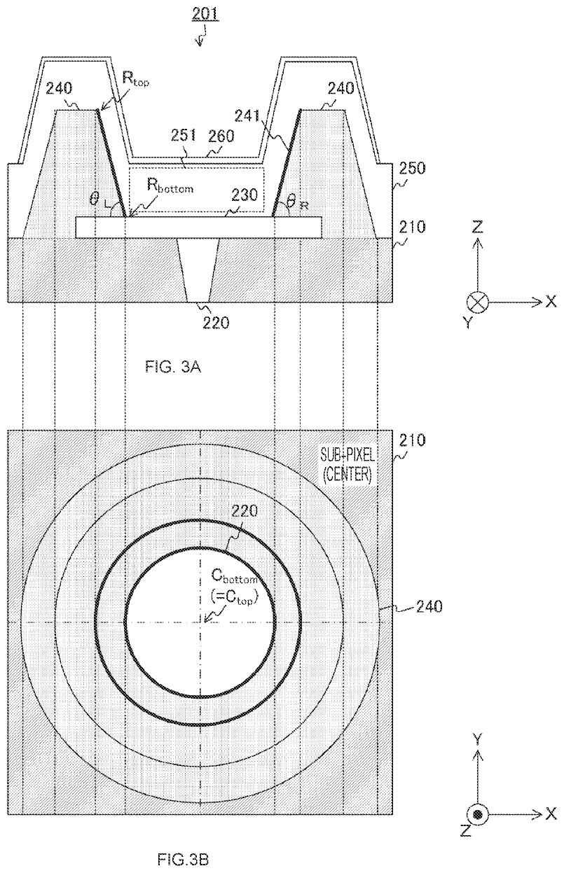

FIG. 3 is an example of a cross-sectional view and a top view of a central sub-pixel 201 according to the first embodiment of the present technology. In the figure, a is the example of the cross-sectional view of the sub-pixel 201, and b in the figure is the example of the top view thereof. The sub-pixel 201 includes an interlayer film 210, a via 220, an anode 230, a reflector 240, an organic light-emitting layer 250, and a cathode 260.

Furthermore, a direction perpendicular to the display surface 105 provided with the sub-pixels 201 is referred to as a “Z direction”, and a horizontal direction parallel to the display surface 105 is referred to as an “X direction”. A perpendicular direction perpendicular to the X direction and the Z direction is referred to as a “Y direction”. In the figure, a is the cross-sectional view of the sub-pixel 201 as viewed from the Y direction, and b in the figure is the top view of the sub-pixel 201 as viewed from the Z direction.

As illustrated in a of the figure, the via 220 is provided in the interlayer film 210. With a direction toward the cathode 260 as an upward direction, the anode 230 is provided on the top of the interlayer film 210. The anode 230 is connected to a pixel circuit (not illustrated) in the sub-pixel 201 through the via 220.

Furthermore, the reflector 240 is formed around the anode 230. The refractive index of the reflector 240 is lower than that of the organic light-emitting layer 250. As the material of the reflector 240, for example, silicon oxide (SiO) is used. Furthermore, the reflector 240 becomes narrower (in other words, is tapered) along the Z direction. This taper forms a cone-shaped reflecting surface 241 on the inside of the reflector 240. Thick lines on the surface of the reflector 240 in the figure indicate the reflecting surface 241.

Furthermore, the organic light-emitting layer 250 is formed on the tops of the anode 230 and the reflector 240. The structure of the organic light-emitting layer 250 is typically a laminated structure with a charge injection layer, a charge transport layer, a light-emitting layer, an electron transport layer, and an electron injection layer. The cathode 260 is provided on the top of the organic light-emitting layer 250. The cathode 260 is typically a thin film of metal such as magnesium or silver, or a transparent electrode of indium zinc oxide (IZO) or the like. On the top of the cathode 260, a protective film, a sealing resin, glass, etc. are further formed, which are not illustrated in the figure.

The anode 230 and the cathode 260 apply a voltage to the organic light-emitting layer 250. Of the organic light-emitting layer 250, a light-emitting portion 251 that is a portion sandwiched between the anode 230 and the cathode 260 emits light when the applied voltage varies. Light from the light-emitting portion 251 is totally reflected at an interface between the light-emitting portion 251 and the reflector 240 having the lower refractive index (that is, the reflecting surface 241).

A contact point between the anode 230 and the reflecting surface 241 is referred to as a reflector bottom R_{bottom}, and a set of the reflector bottoms R_{bottom} is referred to as a “bottom contour line”. On the other hand, a point on the reflecting surface 241 farthest from the anode 230 is referred to as a reflector top Rₜₒₚ, and a set of the reflector tops Rₜₒₚ is referred to as a “top contour line”. In b of the figure, an outer thick line indicates the top contour line, and an inner thick line indicates the bottom contour line. Note that in b of the figure, the top contour line and the bottom contour line are circles, but are not limited to circles and may be ellipses or the like.

Furthermore, an angle formed by the left reflecting surface 241 and the anode 230 when viewed from a predetermined direction parallel to the display surface 105 (such as the Y direction) is referred to as a taper angle θ_{L}, and an angle formed by the right reflecting surface 241 and the anode 230 is referred to as a taper angle θ_{R}.

As illustrated in a of the figure, at the central sub-pixel 201, the left taper angle θ_{L} and the right taper angle θ_{R} substantially agree when viewed from any direction as long as the direction is parallel to the display surface 105 (such as the X direction or the Y direction). Here, “substantially agree” means that the two values exactly agree or that the difference between them is within a predetermined allowable value.

Since the left taper angle θ_{L} and the right taper angle θ_{R} substantially agree, the center of gravity C_{bottom} of the bottom contour line substantially coincides with the center of gravity Cₜₒₚ of the top contour line as illustrated in b of the figure. This symmetrical structure of the reflector 240 allows the central reflector 240 to reflect light from the light-emitting portion 251 in the Z direction.

Here, light emitted by the respective organic light-emitting layers 250 of the three sub-pixels 201 in each pixel 200 is, for example, R, G, and B. The colors of light emitted by the organic light-emitting layers 250 can be changed by changing organic molecules in the layers. Since the organic light-emitting layers 250 emit light of R, G, and B, a color image can be displayed without color filters. Note that color filters may be provided at the sub-pixels 201 as will be described later.

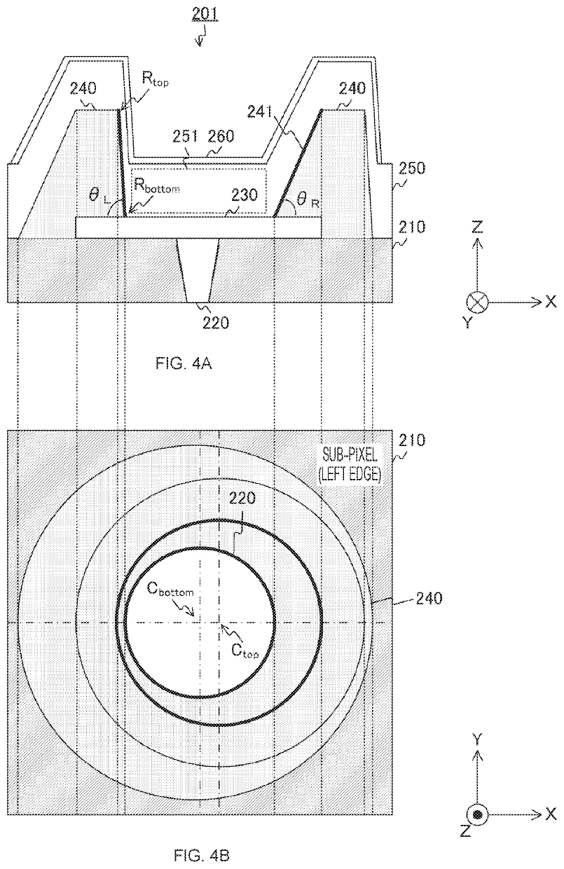

FIG. 4 is an example of a cross-sectional view and a top view of a sub-pixel 201 at the left edge of the display surface 105 as viewed from the Z direction according to the first embodiment of the present technology. In the figure, a is the example of the cross-sectional view of the sub-pixel 201, and b in the figure is the example of the top view thereof.

Like the central sub-pixel 201, the leftmost sub-pixel 201 includes an interlayer film 210, a via 220, an anode 230, a reflector 240, an organic light-emitting layer 250, and a cathode 260.

However, as illustrated in a of the figure, in the leftmost sub-pixel 201, the left taper angle θ_{L} is larger than the right taper angle θ_{R}. Therefore, as illustrated in b of the figure, the center of gravity Cₜₒₚ of the top contour line does not coincide with the center of gravity C_{bottom} of the bottom contour line, and the center of gravity Cₜₒₚ is shifted to the right. This asymmetric structure of the reflector 240 allows the leftmost reflector 240 to reflect light from a light-emitting portion 251 in a direction toward the central axis of the display surface 105.

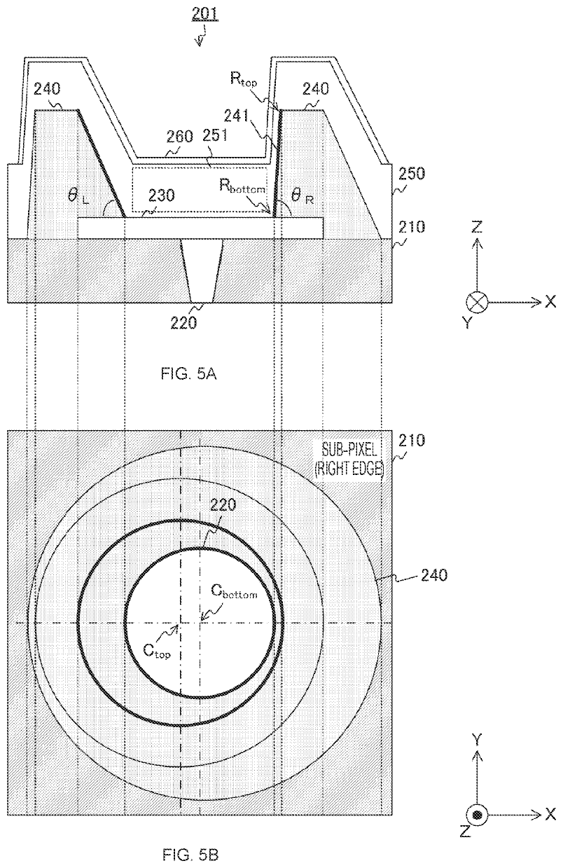

FIG. 5 is an example of a cross-sectional view and a top view of a sub-pixel 201 at the right edge of the display surface 105 as viewed from the Z direction according to the first embodiment of the present technology. In the figure, a is the example of the cross-sectional view of the sub-pixel 201, and b in the figure is the example of the top view thereof.

Like the central sub-pixel 201, the rightmost sub-pixel 201 includes an interlayer film 210, a via 220, an anode 230, a reflector 240, an organic light-emitting layer 250, and a cathode 260.

However, as illustrated in a of the figure, in the rightmost sub-pixel 201, the left taper angle θ_{L} is smaller than the right taper angle θ_{R}. Therefore, as illustrated in b of the figure, the center of gravity Cₜₒₚ of the top contour line does not coincide with the center of gravity C_{bottom} of the bottom contour line, and the center of gravity Cₜₒₚ is shifted to the left. This asymmetric structure of the reflector 240 allows the rightmost reflector 240 to reflect light from a light-emitting portion 251 in a direction toward the central axis of the display surface 105.

### Configuration Example of Pixel Array

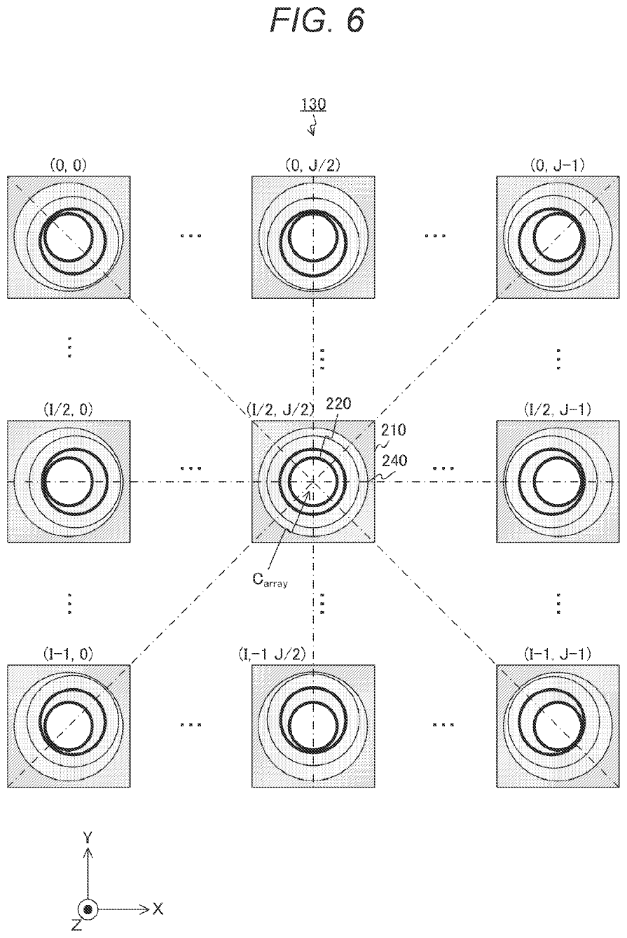

FIG. 6 is an example of a top view of the pixel array 130 according to the first embodiment of the present technology. I is the number of rows of the pixel array 130 (I is an integer), and J is the number of columns (J is an integer). (i, j) is an address assigned to each sub-pixel 201. i is an integer from 0 to I-1, and j is an integer from 0 to J-1.

Furthermore, C_{array} is the center of the display surface 105 on which the sub-pixels 201 are arranged. In the vicinity of the center C_{array}, for example, at the sub-pixel 201 of address (I/2, J/2), the center of gravity of the top contour line (outer thick line) and the center of gravity of the bottom contour line (inner thick line) substantially coincide as illustrated in the figure.

On the other hand, the farther the sub-pixel 201 is from the center C_{array}, the larger the distance between the center of gravity of the top contour line and the center of gravity of the bottom contour line, and the more the center of gravity of the top contour line is shifted in a direction toward the center C_{array}.

For example, at the upper left sub-pixel 201 of address (0, 0) when viewed from the Z direction, the center of gravity of the top contour line (outer thick line) is shifted in a lower right direction. At the upper center sub-pixel 201 of address (0, J/2), the center of gravity of the top contour line is shifted in a downward direction. At the upper right sub-pixel 201 of address (0, J-1), the center of gravity of the top contour line is shifted in a lower left direction. At the left center sub-pixel 201 of address (I/2, 0), the center of gravity of the top contour line is shifted in a right direction. At the right center sub-pixel 201 of address (I/2, J-1), the center of gravity of the top contour line is shifted in a left direction. At the lower left sub-pixel 201 of address (I-1, 0), the center of gravity of the top contour line is shifted in an upper right direction. At the lower center sub-pixel 201 of address (I-1, J/2), the center of gravity of the top contour line is shifted in an upward direction. At the lower right sub-pixel 201 of address (I-1, J-1), the center of gravity of the top contour line is shifted in an upper left direction.

The above-described configuration allows the respective reflectors 240 of the sub-pixels 201 to reflect light from the light-emitting portions 251 in directions toward the central axis passing through the center C_{array}.

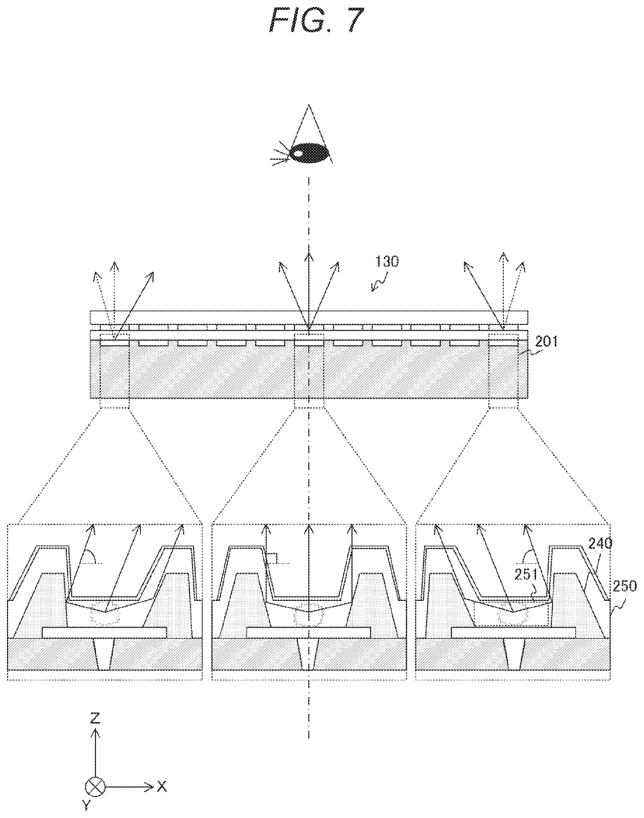

FIG. 7 is a diagram for explaining the reflection directions of the reflectors 240 according to the first embodiment of the present technology. A dot-dash line in the figure indicates the central axis of the display surface. It is assumed that the viewer views an image displayed on the display surface from a line-of-sight direction along this central axis.

In the pixel array 130, each of the plurality of sub-pixels 201 arranged on the display surface is provided with the light-emitting portion 251 and the reflector 240.

As illustrated in the figure, the reflector 240 of the sub-pixel 201 at the center of the display surface reflects light emitted from the light-emitting portion 251 in a direction perpendicular to the display surface. When viewed from the Y direction, the reflector 240 of the sub-pixel 201 on the left side reflects light emitted from the light-emitting portion 251 in a rightward direction. The reflector 240 of the sub-pixel 201 on the right side reflects light emitted from the light-emitting portion 251 in a leftward direction. The angle of the reflected light with respect to the display surface substantially agrees with 90 degrees at the central sub-pixel 201. The difference between the angle and 90 degrees increases with increasing distance from the center.

The above-described configuration allows the reflector 240 at any sub-pixel 201 on the display surface to reflect light emitted from the light-emitting portion in a direction toward the central axis of the display surface (dot-dash line). By thus optimizing the taper angles of the reflector 240 for each pixel, light at any position on the display surface can be directed toward the viewer.

Here, consider, as a comparative example, a typical configuration in which the taper angles of the reflectors 240 at all the sub-pixels 201 are the same.

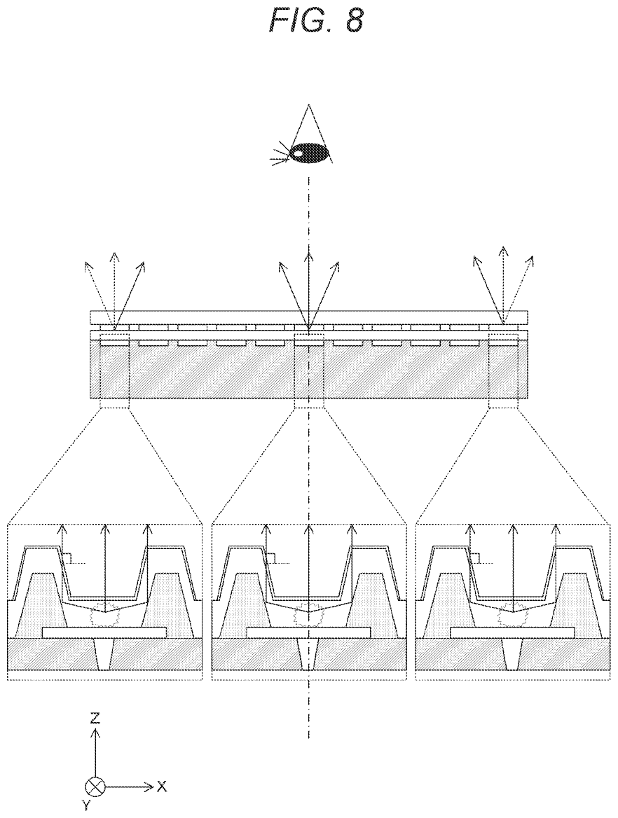

FIG. 8 is a diagram for explaining the reflection directions of the reflectors according to the comparative example. As illustrated in the figure, the reflector 240 of the sub-pixel at any position on the display surface has the same taper angle. Each reflector 240 reflects light emitted from the light-emitting portion in the Z direction perpendicular to the display surface. In this comparative example, light of the sub-pixels near the center is reflected toward the viewer, but light of the sub-pixels at positions away from the center is not reflected toward the viewer.

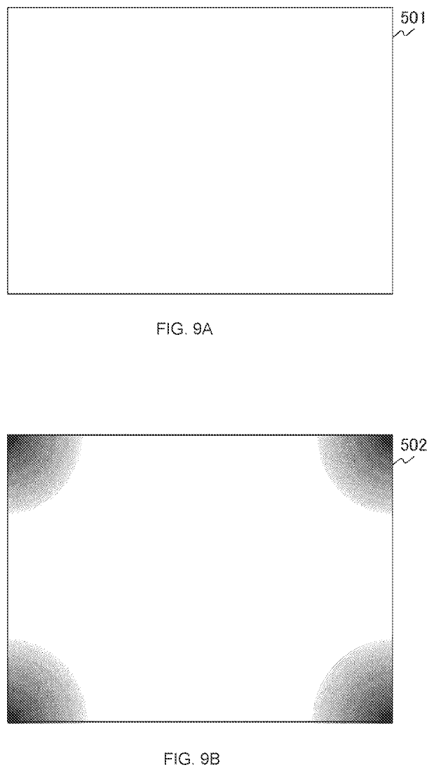

FIG. 9 is a diagram illustrating an example of images viewed by the viewer according to the first embodiment of the present technology and the comparative example. In the figure, a is a diagram illustrating an example of an image 501 when the viewer views the display device 120 of the first embodiment. In the figure, b is a diagram illustrating an example of an image 502 when the viewer views the display device of the comparative example. An image actually displayed by the display devices is, for example, an image in which all the pixels are white. However, the images 501 and 502 in the figure are not the image itself actually displayed on the display devices, but images that the viewer sees during viewing.

As illustrated in a of the figure, in a case where the taper angles of the reflector 240 are optimized for each pixel, unevenness in brightness does not occur in the image 501 viewed by the viewer. This is because light from the light-emitting portion 251 is reflected by the reflector 240 in a direction toward the viewer at any sub-pixel 201 on the display surface.

On the other hand, as illustrated in b of the figure, in the comparative example in which the taper angles of the reflectors 240 are the same at all the pixels, brightness at the edges (upper left, upper right, etc.) of the image 502 viewed by the viewer decreases, causing unevenness in brightness. This is because light of the sub-pixels near the center is reflected toward the viewer, but light of the sub-pixels at positions away from the center is not reflected toward the viewer.

### Method for Manufacturing Display Device

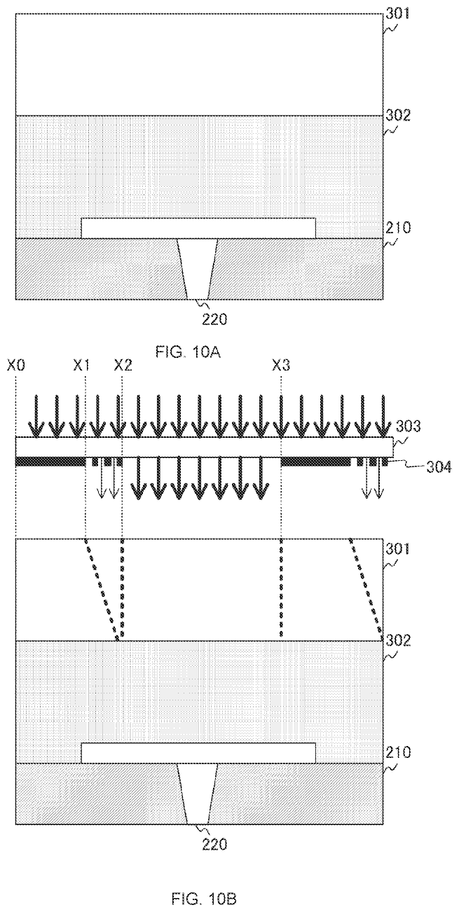

FIG. 10 is a diagram for explaining steps up to gray-tone exposure according to the first embodiment of the present technology. In the figure, a is a diagram for explaining a step of resist application and pre-bake. In the figure, b is a diagram for explaining a step of gray-tone exposure.

As illustrated in a of the figure, a system of manufacturing the display device 120 places, in layers, a low-refractive-index material 302 having a lower refractive index than the organic light-emitting layer 250 on the interlayer film 210 in which the via 220 etc. are formed. Then, the manufacturing system applies a resist 301 to the low-refractive-index material 302 using a spin coating method or the like, and performs pre-bake by hot plate heating or the like.

Next, as illustrated in b of the figure, the manufacturing system performs gray-tone exposure. In the gray-tone mask exposure, a gray-tone mask 304 attached to a glass 303 is used. The gray-tone mask 304 is provided with a slit pattern of a resolution equal to or lower than that of an exposure machine. By portions of the slit pattern blocking part of light, the manufacturing system can perform intermediate exposure. The degree of the intermediate exposure can be adjusted by adjusting the width, density, etc. of the slits. A typical one for i-line resist or a KrF resist or the like is used as the resist 301 in accordance with the wavelength of the exposure machine.

The manufacturing system can adjust the taper angles by adjusting the width or density of the slits of the gray-tone mask 304 in the gray-tone exposure. For example, in a portion from X0 to X1 in b of the figure, the gray-tone mask 304 is not opened, and the resist 301 immediately below this is not exposed. A portion from X1 to X2 of the gray-tone mask 304 has a plurality of slits, and the width thereof gradually increases from X1 to X2. Through these slits, intermediate exposure is performed on the resist 301 immediately below X1 to X2. The amount of the exposure gradually increases from X1 to X2. Consequently, the developed resist 301 can be tapered. Furthermore, the gray-tone mask 304 is opened in a portion from X2 to X3, and the resist 301 immediately below this is exposed. Thick dotted lines in the figure indicate the shape of the developed resist 301 to be described later.

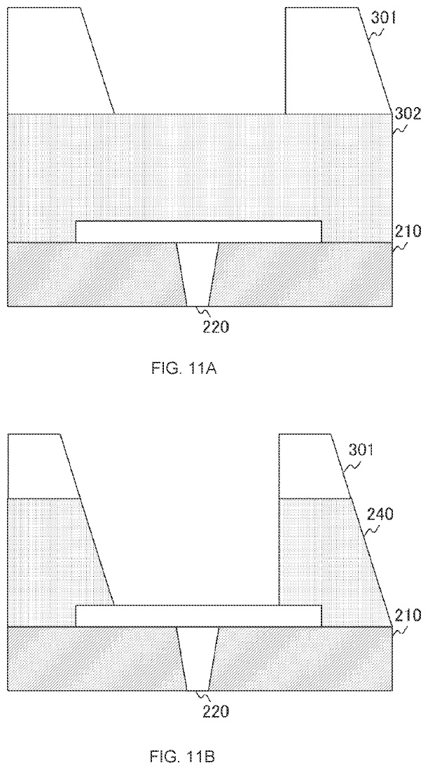

FIG. 11 is a diagram for explaining steps up to dry etching according to the first embodiment of the present technology. In the figure, a is a diagram for explaining a step of development and post-bake. In the figure, b is a diagram for explaining a step of dry etching.

As illustrated in a of the figure, the manufacturing system removes exposed portions of the resist 301 with a predetermined developer. The developed resist 301 has a cone-shaped wall surface. Here, a collection of points on the wall surface farthest from the low-refractive-index material 302 is referred to as a top contour line, and a collection of points of contact between the low-refractive-index material 302 and the wall surface is referred to as a bottom contour line. The distance between the center of gravity of the top contour line and the center of gravity of the bottom contour line increases with increasing distance from the central axis of the display surface. After such a pattern is formed, the manufacturing system performs post-bake by hot plate heating or the like.

Next, as illustrated in b of the figure, the manufacturing system performs dry etching on the low-refractive-index material 302 to transfer the pattern of the developed resist 301 to the low-refractive-index material 302. The low-refractive-index material 302 is also tapered in shape along the tapered shape of the resist 301 by the dry etching, forming the reflector 240 including the low-refractive-index material 302.

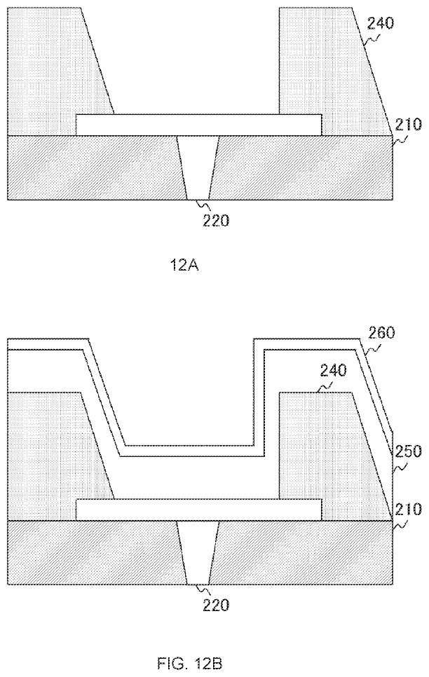

FIG. 12 is a diagram for explaining steps up to pretreatment and vapor deposition according to the first embodiment of the present technology. In the figure, a is a diagram for explaining a step of stripping off the resist 301. In the figure, b is a diagram for explaining a step of pretreatment and vapor deposition.

As illustrated in a of the figure, the manufacturing system removes (ashes) the resist by plasma treatment with oxygen (O₂) or the like, and performs alkali chemical solution treatment (that is, wet treatment) on a small residue to completely remove it.

Next, as illustrated in b of the figure, the manufacturing system performs pretreatment using O₂ plasma and forms the organic light-emitting layer 250 and the cathode 260. Typically, the organic light-emitting layer 250 is formed by vapor deposition or application, and the cathode 260 is formed by vapor deposition or sputtering.

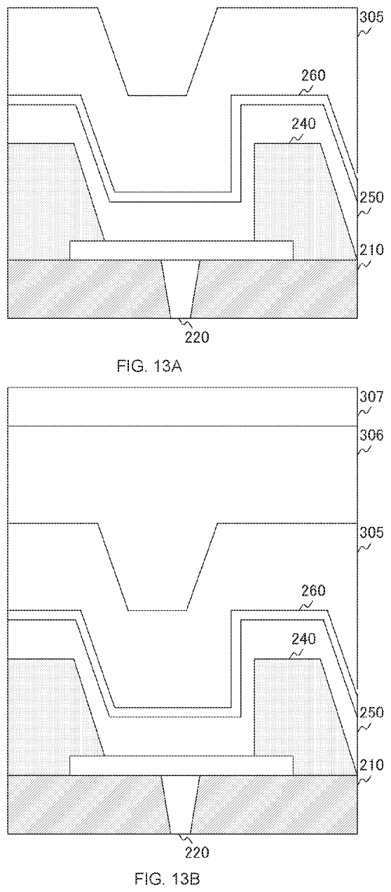

FIG. 13 is a diagram for explaining steps up to sealing according to the first embodiment of the present technology. In the figure, a is a diagram for explaining a step of forming a protective film. In the figure, b is a diagram for explaining a sealing step.

As illustrated in a of the figure, the manufacturing system forms a protective film 305 using chemical vapor deposition (CVD) or the like. The OLEDs are sensitive to moisture, and thus are protected by the protective film 305. As the protective film 305, silicon nitride (SiN) or the like is typically used.

Next, as illustrated in b of the figure, the manufacturing system performs sealing with the sealing resin 306, which is bonded to the glass 307.

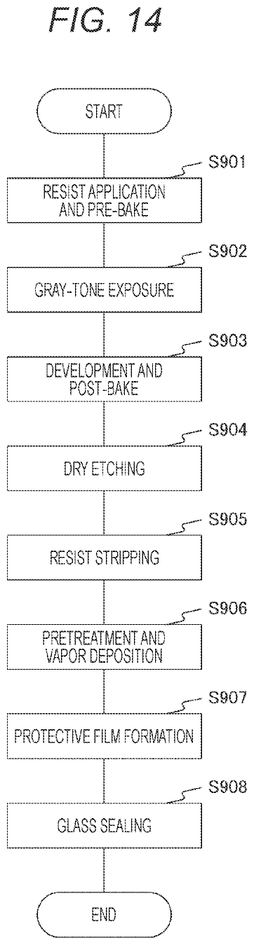

FIG. 14 is a flowchart illustrating an example of the method of manufacturing the display device 120 according to the first embodiment of the present technology. The manufacturing system places the low-refractive-index material 302 on the interlayer film 210 in layers, and performs application of a resist and pre-bake (step S901). Then, the manufacturing system performs gray-tone exposure (step S902), and performs development and post-bake (step S903).

Next, the manufacturing system performs dry etching (step S904) and strips off the resist (step S905). The manufacturing system performs pretreatment and vapor deposition (step S906), and forms a protective film (step S907). Then, the manufacturing system performs sealing using glass etc. (step S908), and completes the operation for manufacturing the display device 120.

As described above, according to the first embodiment of the present technology, since the reflectors 240 reflect light from the light-emitting portions 251 toward the central axis of the display surface 105, it is possible to prevent unevenness in brightness of an image viewed by the viewer along the central axis. Thus, the quality of the image can be improved.

### 2. Second Embodiment

In the first embodiment described above, the respective organic light-emitting layers 250 of the plurality of sub-pixels 201 self-emit light of R, G, and B. However, this configuration requires varying organic molecules in the organic light-emitting layers 250 for different colors, and can complicate the manufacturing process of the organic light-emitting layers 250. The display device 120 of the second embodiment is different from that of the first embodiment in that color filters are further provided at the sub-pixels 201.

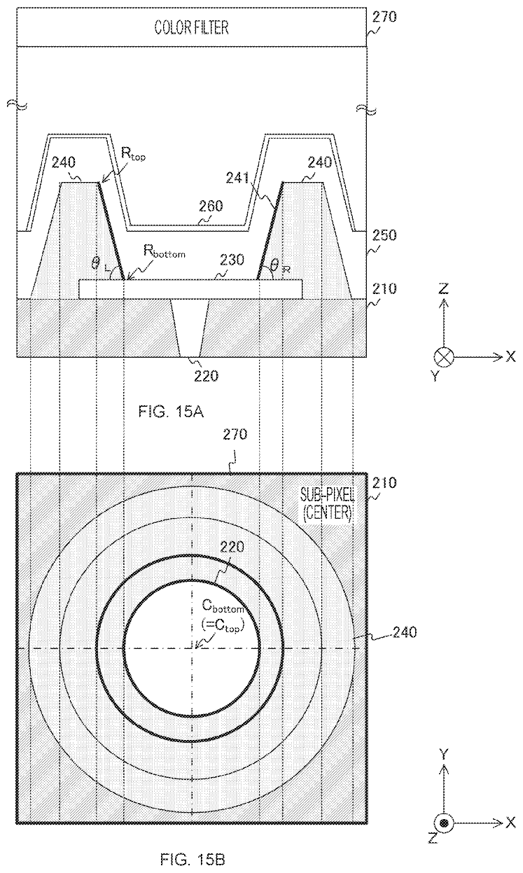

FIG. 15 is an example of a cross-sectional view and a top view of the central sub-pixel 201 according to the second embodiment of the present technology. In the figure, a is the example of the cross-sectional view of the sub-pixel 201, and b in the figure is the example of the top view thereof.

As illustrated in a of the figure, the sub-pixel 201 of the second embodiment is different from that of the first embodiment in that a color filter 270 is further provided. The color filter 270 transmits visible light of a predetermined color (such as one of R, G, or B). Light emitted from the light-emitting portion 251 and light reflected by the reflector 240 pass through the color filter 270 and are output from the display device 120.

Furthermore, the light-emitting portion 251 of the second embodiment emits white light. Furthermore, the respective color filters 270 of the plurality of sub-pixels 201 in each pixel 200 transmit different colors (such as R, G, and B). The arrangement of these color filters 270 allows the display device 120 to display a color image. In addition, the arrangement of the color filters 270 makes it sufficient to self-emit only white light, thus eliminating the need to vary organic molecules for different colors. This can reduce cost compared with the first embodiment in which the color filters 270 are not provided.

Thick lines in b of the figure indicate the four sides of the color filter 270. As illustrated in b of the figure, at the central sub-pixel 201, the center of gravity of the color filter 270 substantially coincides with the center of gravity of the sub-pixel 201.

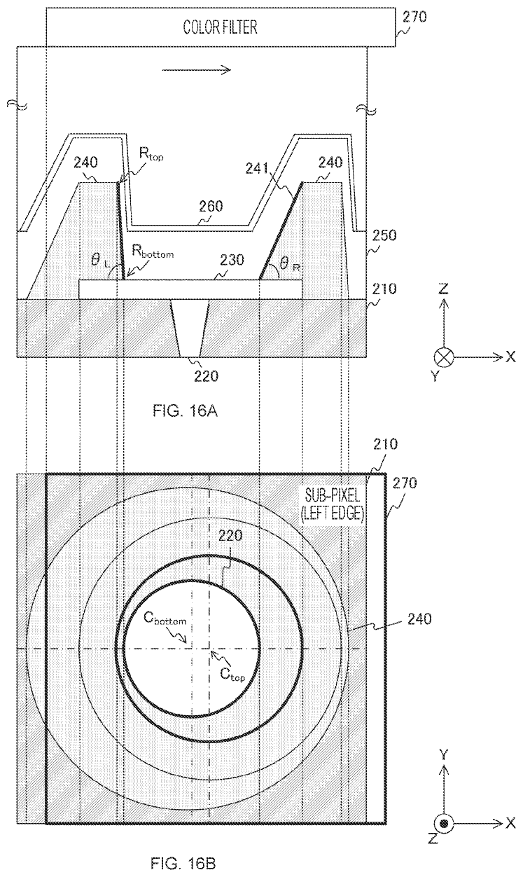

FIG. 16 is an example of a cross-sectional view and a top view of the leftmost sub-pixel 201 according to the second embodiment of the present technology. In the figure, a is the example of the cross-sectional view of the sub-pixel 201, and b in the figure is the example of the top view thereof.

As illustrated in a of the figure, a color filter 270 is also provided at the leftmost sub-pixel 201. However, as illustrated in b of the figure, at the leftmost sub-pixel 201, the center of gravity of the color filter 270 is different from the center of gravity of the sub-pixel 201 and is shifted to the right. On the other hand, at the rightmost sub-pixel 201 (not illustrated), the center of gravity of the color filter 270 is shifted to the left. Likewise, at the other sub-pixels 201 except that at the center, the center of gravity of the color filter 270 is shifted toward the central axis. Then, the distance between the center of gravity of the color filter 270 and the center of gravity of the sub-pixel 201 increases with increasing distance from the central axis of the display surface.

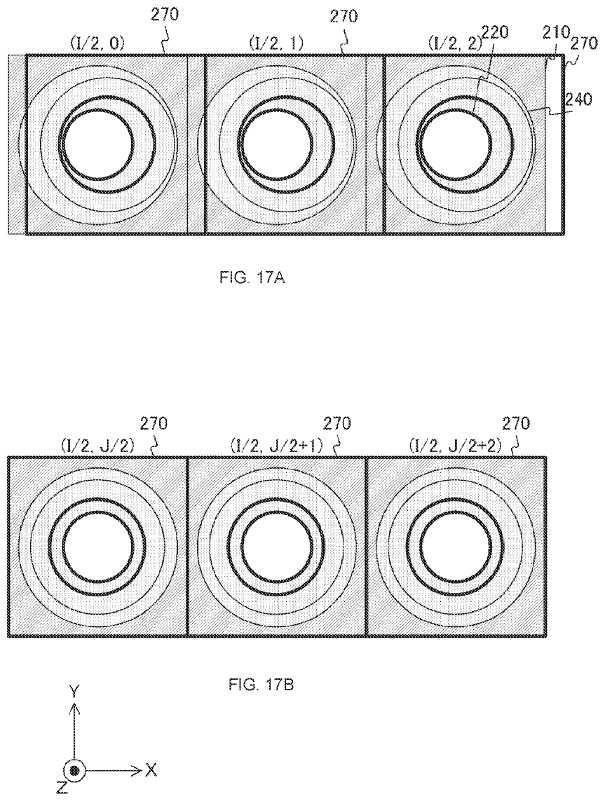

FIG. 17 is an example of top views of leftmost and central sub-pixels 201 according to the second embodiment of the present technology. In the figure, a is an example of a top view of three sub-pixels 201 in a pixel 200 disposed at the left edge. In the figure, b is an example of a top view of three sub-pixels 201 in a pixel 200 disposed at the center.

As illustrated in a of the figure, in each of the three sub-pixels 201 at the center, the center of gravity of the color filter 270 substantially coincides with the center of gravity of the sub-pixel 201. The color filter 270 of address (I/2, 0) near the center transmits, for example, R light, and the color filter 270 of the adjacent address (I/2, 1) transmits, for example, G light. The color filter 270 of the adjacent address (I/2, 2) transmits, for example, B light.

Furthermore, at the leftmost pixel 200, the center of gravity of the color filters 270 is different from the center of gravity of the sub-pixels 201, and is shifted to the left. Furthermore, the distance between the center of gravity of the color filters 270 and the center of gravity of the sub-pixels 201 increases with increasing distance from the central axis. The same applies to the sub-pixels 201 of other addresses such as those at the right edge.

On the other hand, as illustrated in b of the figure, at the central pixel 200, the center of gravity of the color filters 270 substantially coincides with the center of gravity of the sub-pixels 201.

As described above, by shifting the center of gravity of the color filters 270 according to the distance from the central axis of the display surface, the viewing angle of each color can be widened.

Thus, according to the second embodiment of the present technology, since the distance between the center of gravity of the color filters 270 and the center of gravity of the sub-pixels 201 is increased with increasing distance from the central axis, the viewing angle of each color can be widened. In addition, the arrangement of the color filters 270 makes it sufficient to self-emit only white light, thus eliminating the need to vary organic molecules in the organic light-emitting layers 250 for different colors. This can avoid complication of a process of manufacturing the organic light-emitting layers 250 compared to the first embodiment in which the color filters 270 are not provided.

### 3. Example of Application to Mobile Object

The technology according to the present disclosure (the present technology) can be applied to various products. For example, the technology according to the present disclosure may be implemented as an apparatus mounted on any type of mobile object such as an automobile, an electric vehicle, a hybrid electric vehicle, a motorcycle, a bicycle, personal mobility, an airplane, a drone, a ship, or a robot.

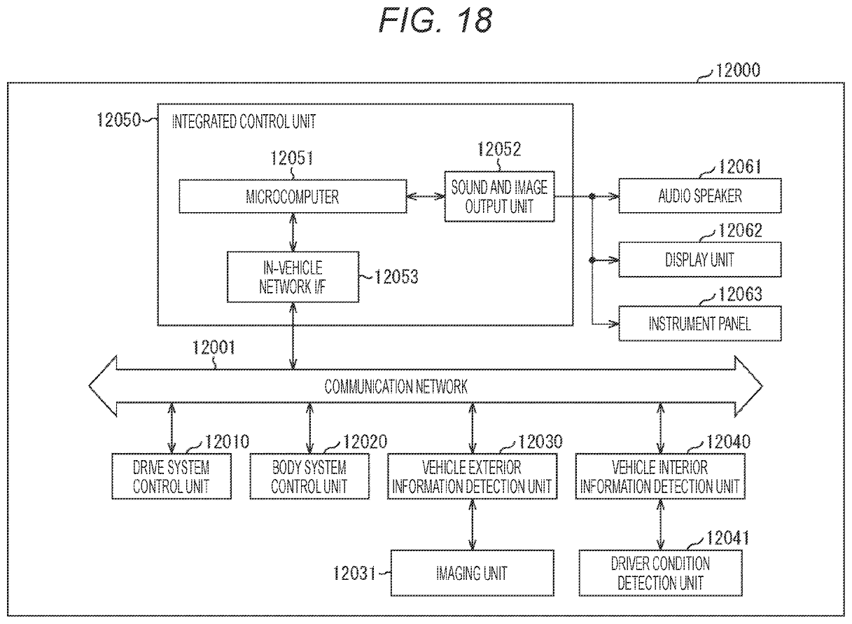

FIG. 18 is a block diagram illustrating a schematic configuration example of a vehicle control system that is an example of a mobile object control system to which the technology according to the present disclosure can be applied.

A vehicle control system 12000 includes a plurality of electronic control units connected via a communication network 12001. In the example illustrated in FIG. 18, the vehicle control system 12000 includes a drive system control unit 12010, a body system control unit 12020, a vehicle exterior information detection unit 12030, a vehicle interior information detection unit 12040, and an integrated control unit 12050. Furthermore, as a functional configuration of the integrated control unit 12050, a microcomputer 12051, a sound and image output unit 12052, and an in-vehicle network interface (I/F) 12053 are illustrated.

The drive system control unit 12010 controls the operation of apparatuses related to the drive system of the vehicle, according to various programs. For example, the drive system control unit 12010 functions as a control device for a driving force generation apparatus for generating a vehicle driving force such as an internal combustion engine or a drive motor, a driving force transmission mechanism for transmitting the driving force to wheels, a steering mechanism for adjusting the steering angle of the vehicle, a breaking apparatus for generating a vehicle braking force, etc.

The body system control unit 12020 controls the operation of various apparatuses mounted on the vehicle body, according to various programs. For example, the body system control unit 12020 functions as a control device for a keyless entry system, a smart key system, power window devices, or various lamps such as headlamps, back lamps, brake lamps, indicators, or fog lamps. In this case, the body system control unit 12020 can receive the input of radio waves transmitted from a portable device substituted for a key or signals from various switches. The body system control unit 12020 receives the input of these radio waves or signals, and controls door lock devices, the power window devices, the lamps, etc. of the vehicle.

The vehicle exterior information detection unit 12030 detects information on the exterior of the vehicle equipped with the vehicle control system 12000. For example, an imaging unit 12031 is connected to the vehicle exterior information detection unit 12030. The vehicle exterior information detection unit 12030 causes the imaging unit 12031 to capture an image outside the vehicle and receives the captured image. The vehicle exterior information detection unit 12030 may perform object detection processing or distance detection processing on persons, vehicles, obstacles, signs, characters on the road surface, etc. on the basis of the received image.

The imaging unit 12031 is an optical sensor that receives light and outputs an electric signal corresponding to the amount of the received light. The imaging unit 12031 may output the electric signal as an image, or may output it as distance measurement information. Furthermore, light received by the imaging unit 12031 may be visible light, or may be invisible light such as infrared rays.

The vehicle interior information detection unit 12040 detects information on the vehicle interior. For example, a driver condition detection unit 12041 that detects the driver's conditions is connected to the vehicle interior information detection unit 12040. The driver condition detection unit 12041 includes, for example, a camera that images the driver. The vehicle interior information detection unit 12040 may calculate the degree of fatigue or the degree of concentration of the driver, or may determine whether the driver is dozing, on the basis of detected information input from the driver condition detection unit 12041.

The microcomputer 12051 can calculate a control target value for the driving force generation apparatus, the steering mechanism, or the breaking apparatus on the basis of vehicle interior or exterior information acquired by the vehicle exterior information detection unit 12030 or the vehicle interior information detection unit 12040, and output a control command to the drive system control unit 12010. For example, the microcomputer 12051 can perform cooperative control for the purpose of implementing the functions of an advanced driver assistance system (ADAS) including vehicle collision avoidance or impact mitigation, following driving based on inter-vehicle distance, vehicle speed-maintaining driving, vehicle collision warning, vehicle lane departure warning, etc.

Furthermore, the microcomputer 12051 can perform cooperative control for the purpose of automatic driving for autonomous travelling without the driver's operation etc., by controlling the driving force generation apparatus, the steering mechanism, the breaking apparatus, etc. on the basis of information in or around the vehicle acquired by the vehicle exterior information detection unit 12030 or the vehicle interior information detection unit 12040.

Moreover, the microcomputer 12051 can output a control command to the body system control unit 12020 on the basis of vehicle exterior information acquired by the vehicle exterior information detection unit 12030. For example, the microcomputer 12051 can perform cooperative control for the purpose of preventing glare by controlling the headlamps according to the position of a preceding vehicle or an oncoming vehicle detected by the vehicle exterior information detection unit 12030, switching high beam to low beam, or the like.

The sound and image output unit 12052 transmits an output signal of at least one of a sound or an image to an output device that can visually or auditorily notify a vehicle occupant or the outside of the vehicle of information. In the example of FIG. 18, as the output device, an audio speaker 12061, a display unit 12062, and an instrument panel 12063 are illustrated. The display unit 12062 may include at least one of an on-board display or a head-up display, for example.

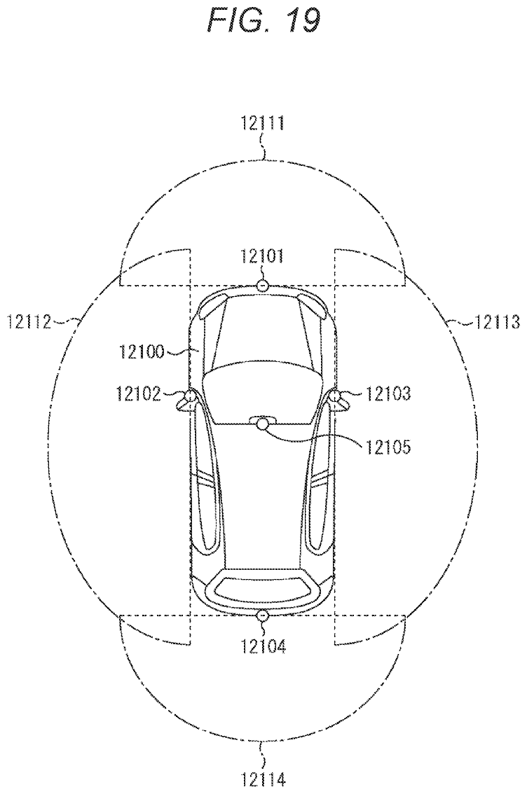

FIG. 19 is a diagram illustrating an example of the installation position of the imaging unit 12031.

In FIG. 19, as the imaging unit 12031, imaging units 12101, 12102, 12103, 12104, and 12105 are included.

The imaging units 12101, 12102, 12103, 12104, and 12105 are provided, for example, at positions such as the front nose, the side mirrors, the rear bumper, the back door, and an upper portion of the windshield in the vehicle compartment of the vehicle 12100. The imaging unit 12101 provided at the front nose and the imaging unit 12105 provided at the upper portion of the windshield in the vehicle compartment mainly acquire images of the front of the vehicle 12100. The imaging units 12102 and 12103 provided at the side mirrors mainly acquire images of the sides of the vehicle 12100. The imaging unit 12104 provided at the rear bumper or the back door mainly acquires an image of the rear of the vehicle 12100. The imaging unit 12105 provided at the upper portion of the windshield in the vehicle compartment is mainly used for detection of a preceding vehicle, or pedestrians, obstacles, traffic lights, traffic signs, lanes, etc.

Note that FIG. 19 illustrates an example of imaging ranges of the imaging units 12101 to 12104. An imaging range 12111 indicates the imaging range of the imaging unit 12101 provided at the front nose. Imaging ranges 12112 and 12113 indicate the imaging ranges of the imaging units 12102 and 12103 provided at the side mirrors, respectively. An imaging range 12114 indicates the imaging range of the imaging unit 12104 provided at the rear bumper or the back door. For example, by laying image data captured by the imaging units 12101 to 12104 on top of each other, an overhead image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging devices, or may be an imaging device including pixels for phase difference detection.

For example, the microcomputer 12051 can determine distances to three-dimensional objects in the imaging ranges 12111 to 12114, and temporal changes in the distances (relative speeds to the vehicle 12100), on the basis of distance information obtained from the imaging units 12101 to 12104, thereby especially extracting, as a preceding vehicle, the nearest three-dimensional object located on the traveling path of the vehicle 12100 which is a three-dimensional object traveling at a predetermined speed (e.g., 0 km/h or higher) in substantially the same direction as the vehicle 12100. Furthermore, the microcomputer 12051 can perform automatic brake control (including following stop control), automatic acceleration control (including following start control), etc., setting an inter-vehicle distance to be provided in advance in front of a preceding vehicle. Thus, the cooperative control for the purpose of autonomous driving for autonomous traveling without the driver's operation etc. can be performed.

For example, the microcomputer 12051 can extract three-dimensional object data regarding three-dimensional objects, classifying them into a two-wheel vehicle, an ordinary vehicle, a large vehicle, a pedestrian, and another three-dimensional object such as a power pole, on the basis of distance information obtained from the imaging units 12101 to 12104, for use in automatic avoidance of obstacles. For example, for obstacles around the vehicle 12100, the microcomputer 12051 distinguishes between obstacles that can be visually recognized by the driver of the vehicle 12100 and obstacles that are difficult to visually recognize. Then, the microcomputer 12051 determines a collision risk indicating the degree of danger of collision with each obstacle. In a situation where the collision risk is equal to or higher than a set value and there is a possibility of collision, the microcomputer 12051 can perform driving assistance for collision avoidance by outputting a warning to the driver via the audio speaker 12061 or the display unit 12062, or performing forced deceleration or avoidance steering via the drive system control unit 12010.

At least one of the imaging units 12101 to 12104 may be an infrared camera that detects infrared rays. For example, the microcomputer 12051 can recognize a pedestrian by determining whether or not a pedestrian is present in images captured by the imaging units 12101 to 12104. The recognition of a pedestrian is performed, for example, by a step of extracting feature points in images captured by the imaging units 12101 to 12104 as infrared cameras, and a step of performing pattern matching on a series of feature points indicating the outline of an object to determine whether or not it is a pedestrian. When the microcomputer 12051 determines that a pedestrian is present in images captured by the imaging units 12101 to 12104 and recognizes the pedestrian, the sound and image output unit 12052 controls the display unit 12062 to superimpose and display a rectangular outline for emphasis on the recognized pedestrian. Alternatively, the sound and image output unit 12052 may control the display unit 12062 so as to display an icon or the like indicating the pedestrian at a desired position.

An example of the vehicle control system to which the technology according to the present disclosure can be applied has so far been described. The technology according to the present disclosure can be applied to the display unit 12062 in the configuration described above. Specifically, the display device 120 in FIG. 2 can be applied to the display unit 12062. The application of the technology according to the present disclosure to the display unit 12062 can prevent unevenness in brightness to display an image easier to see, and thus can reduce driver fatigue.

Note that the above-described embodiments show an example for embodying the present technology, and matters in the embodiments and matters specifying the invention in the claims have one-to-one correspondence relationships. Likewise, matters specifying the invention in the claims and matters to which the same names as these are assigned in the embodiments of the present technology have one-to-one correspondence relationships. However, the present technology is not limited to the embodiments, and can be embodied by making various modifications to the embodiments without departing from the scope thereof.

Note that the effects described in the present description are merely examples and non-limiting, and other effects may be included.

Note that the present technology can also have the following configurations.

(1) A display device including a pixel array in which a plurality of sub-pixels is arranged on a predetermined display surface, each sub-pixel being provided with a light-emitting portion and a reflector that reflects light emitted from the light-emitting portion in a direction toward the central axis of the display surface.

(2) The display device according to (1) above, in which

a difference between an angle of the light reflected by the reflector with respect to the display surface and 90 degrees decreases with increasing distance from the central axis.

(3) The display device according to (1) or (2) above, in which

each of the plurality of sub-pixels is further provided with an anode and a cathode that apply a voltage to the light-emitting portion,

the reflector is formed around the anode,

the reflector has a cone-shaped reflecting surface, and

a distance between the center of gravity of a top contour line that is a collection of points on the reflecting surface farthest from the anode and the center of gravity of a bottom contour line that is a collection of points of contact between the anode and the reflecting surface increases with increasing distance from the central axis to the light-emitting portion.

(4) The display device according to any one of (1) to (3) above, in which each of the plurality of sub-pixels is further provided with a color filter that transmits visible light of a predetermined color.

(5) The display device according to (4) above, in which

a distance between the center of gravity of the color filter and the center of gravity of the sub-pixel increases with increasing distance from the central axis to the sub-pixel.

(6) An electronic device including:

a pixel array in which a plurality of sub-pixels is arranged on a predetermined display surface, each sub-pixel being provided with a light-emitting portion and a reflector that reflects light emitted from the light-emitting portion in a direction toward the central axis of the display surface; and

a driver that drives each of the plurality of sub-pixels.

(7) A method for manufacturing a display device, including:

an application step of applying a predetermined resist to a predetermined low-refractive-index material having a lower refractive index than a predetermined organic light-emitting layer;

an exposure step of exposing the resist to light by gray-tone exposure;

a development step of removing an exposed portion of the resist with a predetermined developer; and

an etching step of transferring a pattern of the resist from which the exposed portion has been removed to the low-refractive-index material by etching the low-refractive-index material.

(8) The method for manufacturing the display device according to (7) above, in which

the resist from which the exposed portion has been removed has a cone-shaped wall surface, and

a distance between the center of gravity of a top contour line that is a collection of points on the wall surface farthest from the low-refractive-index material and the center of gravity of a bottom contour line that is a collection of points of contact between the low-refractive-index material and the wall surface increases with increasing distance from the central axis of a predetermined display surface.

### REFERENCE SIGNS LIST

100 Electronic device

105 Display surface

110 Battery

120 Display device

121 Control circuit

122 H driver

123 V driver

130 Pixel array

200 Pixel

201 Sub-pixel

210 Interlayer film

220 Via

230 Anode

240 Reflector

241 Reflecting surface

250 Organic light-emitting layer

251 Light-emitting portion

260 Cathode

270 Color filter

301 Resist

302 Low-refractive-index material

303, 307 Glass

304 Gray-tone mask

305 Protective film

306 Sealing resin

12062 Display unit

1. A display device comprising a pixel array in which a plurality of sub-pixels is arranged on a predetermined display surface, each sub-pixel being provided with a light-emitting portion and a reflector that reflects light emitted from the light-emitting portion in a direction toward a central axis of the display surface.

2. The display device according to claim 1, wherein
a difference between an angle of the light reflected by the reflector with respect to the display surface and 90 degrees decreases with increasing distance from the central axis.

3. The display device according to claim 1, wherein
each of the plurality of sub-pixels is further provided with an anode and a cathode that apply a voltage to the light-emitting portion,
the reflector is formed around the anode,
the reflector has a cone-shaped reflecting surface, and
a distance between a center of gravity of a top contour line that is a collection of points on the reflecting surface farthest from the anode and a center of gravity of a bottom contour line that is a collection of points of contact between the anode and the reflecting surface increases with increasing distance from the central axis to the light-emitting portion.

4. The display device according to claim 1, wherein each of the plurality of sub-pixels is further provided with a color filter that transmits visible light of a predetermined color.

5. The display device according to claim 4, wherein
a distance between a center of gravity of the color filter and a center of gravity of the sub-pixel increases with increasing distance from the central axis to the sub-pixel.

6. An electronic device comprising:
a pixel array in which a plurality of sub-pixels is arranged on a predetermined display surface, each sub-pixel being provided with a light-emitting portion and a reflector that reflects light emitted from the light-emitting portion in a direction toward a central axis of the display surface; and
a driver that drives each of the plurality of sub-pixels.

7. A method for manufacturing a display device, comprising:
an application step of applying a predetermined resist to a predetermined low-refractive-index material having a lower refractive index than a predetermined organic light-emitting layer;
an exposure step of exposing the resist to light by gray-tone exposure;
a development step of removing an exposed portion of the resist with a predetermined developer; and
an etching step of transferring a pattern of the resist from which the exposed portion has been removed to the low-refractive-index material by etching the low-refractive-index material.

8. The method for manufacturing the display device according to claim 7, wherein
the resist from which the exposed portion has been removed has a cone-shaped wall surface, and
a distance between a center of gravity of a top contour line that is a collection of points on the wall surface farthest from the low-refractive-index material and a center of gravity of a bottom contour line that is a collection of points of contact between the low-refractive-index material and the wall surface increases with increasing distance from a central axis of a predetermined display surface.
